(19) United States
(12) Patent Application Publication
(10) Pub. No.: US 2018/0211828 A1
(43) Pub. Date: Jul. 26, 2018

(54) COMPOSITION FOR FORMING FILM FOR USE IN CLEANING SEMICONDUCTOR SUBSTRATE, AND CLEANING METHOD FOR SEMICONDUCTOR SUBSTRATE

(71) Applicant: JSR CORPORATION, Tokyo (JP)

(72) Inventors: Kang-go CHUNG, Tokyo (JP); Yuushi Matsumura, Tokyo (JP); Yoshio Takimoto, Tokyo (JP)

(73) Assignee: JSR CORPORATION, Tokyo (JP)

(21) Appl. No.: 15/934,258

(22) Filed: Mar. 23, 2018

Related U.S. Application Data
(63) Continuation of application No. PCT/JP2016/073501, filed on Aug. 9, 2016.

(30) Foreign Application Priority Data
Sep. 30, 2015 (JP) 2015-195126

(51) Int. Cl. H01L 21/02; C08L 67/02; C08L 67/04

(52) U.S. Cl. CPC H01L 21/02052; C08L 67/02; H01L 21/31127; C08L 2203/16; C08L 67/04

(57) ABSTRACT

A composition for forming a film for use in cleaning a semiconductor substrate includes a solvent and a compound having a molecular weight of no s less than 300 and comprising a polar group, a group represented by a formula (i) or a combination thereof. In the formula (i), R¹ represents a group that is dissociated by heat or an action of an acid. The polar group is preferably a hydroxy group, a carboxy group, an amide group, an amino group, a sulfonyl group, a sulfo group or a combination thereof. The compound is preferably a polymer having a weight average molecular weight of no less than 300 and no greater than 50,000. The polymer is preferably a ring polymer having a weight average molecular weight of no less than 300 and no greater than 3,000.

—O—R¹ (i)

### CROSS-REFERENCE TO RELATED APPLICATIONS

The present application is a continuation application of International Application No. PCT/JP2016/073501, filed Aug. 9, 2016, which claims priority to Japanese Patent Application No. 2015-195126, filed Sep. 30, 2015. The contents of these applications are incorporated herein by reference in their entirety.

### BACKGROUND OF THE INVENTION

### Field of the Invention

The present invention relates to a composition for forming a film for use in cleaning a semiconductor substrate, and a cleaning method for a semiconductor substrate.

### Discussion of the Background

In production processes of semiconductor substrates, cleaning is conducted in order to remove contaminants such as particles attached onto the surface of the substrates having a pattern formed thereon. In recent years, miniaturization of the formed pattern, and an increase of the aspect ratio have advanced. In cleaning through using a liquid and/or gas, it is difficult to achieve the flow of the liquid and/or gas between the pattern walls in the vicinity of a substrate surface, thereby making removal of fine particles and/or the attached particles between the pattern walls difficult.

Japanese Unexamined Patent Application, Publication No. H7-74137 discloses a method in which after feeding a coating liquid on a substrate surface to provide a thin film, detachment with an adhesive tape removes particles on the substrate surface. According to this method, fine particles and the particles between pattern walls can be reportedly removed at a high removal rate while influences on the semiconductor substrate are decreased.

Japanese Unexamined Patent Application, Publication No. 2014-99583 discloses an apparatus for cleaning a substrate, and a cleaning method for a substrate, in which a treatment liquid for forming a film on a substrate surface is supplied and solidified or hardened, and then the entire treatment liquid solidified or hardened is dissolved in a removing liquid to remove particles on the substrate surface. Although the detailed description of the invention discloses a top coating liquid as a non-limiting example of the treatment liquid, a detailed description as to which treatment liquid is suited is not found.

### SUMMARY OF THE INVENTION

According to one aspect of the present invention, a composition for forming a film for use in cleaning a semiconductor substrate includes a solvent and a compound having a molecular weight of no less than 300 and comprising a polar group, a group represented by a formula (i) or a combination thereof.

—O—R¹ (i)

In the formula (i), R¹ represents a group that is dissociated by heat or an action of an acid.

According to another aspect of the present invention, a cleaning method for a semiconductor substrate includes applying the composition on a surface of the semiconductor substrate to form a film for cleaning the semiconductor substrate. The film is removed from the substrate.

### BRIEF DESCRIPTION OF THE DRAWINGS

FIG. 1A shows an explanatory view illustrating a cleaning method for a semiconductor substrate carried out using a composition for forming a film for use in cleaning a semiconductor substrate of an embodiment of the present invention;

FIG. 1B shows an explanatory view illustrating the cleaning method for a semiconductor substrate carried out using the composition for forming a film for use in cleaning a semiconductor substrate of the embodiment of the present invention; and

FIG. 1C shows an explanatory view illustrating the cleaning method for a semiconductor substrate carried out using the composition for forming a film for use in cleaning a semiconductor substrate of the embodiment of the present invention.

### DESCRIPTION OF EMBODIMENTS

According to an embodiment of the invention, a composition for forming a film for use in cleaning a semiconductor substrate comprises: a compound (hereinafter, may be also referred to as “(A) compound”) having a molecular weight of no less than 300 and comprising a polar group, a group represented by formula (i) (hereinafter, may be also referred to as “group (i)”):

—O—R¹ (i)

wherein in the formula (i), R¹ represents a group that is dissociated by heat or an action of an acid, or

a combination thereof; and
a solvent (hereinafter, may be also referred to as (B) solvent).

According to another embodiment of the invention, a cleaning method for a semiconductor substrate comprises: applying the composition on a surface of the semiconductor substrate to form a film for cleaning the semiconductor substrate; and removing the film from the substrate.

The term “polar group” as referred to herein means a group having at least one hetero atom, except for groups corresponding to the group (i).

In accordance with the embodiments of the present invention, a composition for forming a film for use in cleaning a semiconductor substrate and a cleaning method for a semiconductor substrate that are capable of efficiently removing particles on the substrate surface, and enables the formed film to be easily removed from the substrate surface, are provided. Specifically, according to the composition for forming a film for use in cleaning a semiconductor substrate of the embodiment of the present invention, in processes of removing unwanted substances on the substrate surface through forming a film on the substrate surface, the composition is capable of efficiently removing particles on the substrate surface, and enables the formed film to be easily removed from the substrate surface. Furthermore, the cleaning method for a semiconductor substrate of the another embodiment of the present invention is capable of efficiently removing particles on the substrate surface, while easily removing the formed film from the substrate surface. Therefore, the composition for forming a film for use in cleaning a semiconductor substrate, and the cleaning method for a semiconductor substrate of the embodiments of the present invention can be suitably used in production of semiconductor elements in which further progress of miniaturization, and an increase of the aspect ratio are expected in the future. Hereinafter, the embodiments are explained in detail.

### Composition for Forming Film for Use in Cleaning Semiconductor Substrate

The composition for forming a film for use in cleaning a semiconductor substrate according to an embodiment of the present invention (hereinafter, may be also merely referred to as “film-forming composition for cleaning”) is a composition used for cleaning semiconductor substrates. A film is formed on the surface of a semiconductor substrate using the film-forming composition for cleaning, and then particles attached to the surface of the substrate, particularly between pattern walls and the like can be efficiently removed by removing the film.

The film-forming composition for cleaning contains the compound (A) and the solvent (B). Since the compound (A) has a molecular weight of no less than 300 and includes the polar group and/or the group (i), it is presumed that the film-forming composition for cleaning exhibits proper wet spreadability on substrate surfaces, and the formed film has an affinity to the removing liquid and a proper rate of dissolution, thereby allowing the particles on the substrate surface to be rapidly removed in a state in which the particles are covered by the film, leading to an achievement of a high efficiency of removal. In particular, in the case of the compound (A) including the group (i), it is presumed that: due to the polar group being generated when R¹ in the formula (i) is dissociated by heat, the formed film has an increased affinity to and an increased rate of dissolution in the removing liquid; and due to the dissociated group being volatilized, detachment of the particles from the substrate surface is promoted, leading to an achievement of the higher efficiency of removal.

The film-forming composition for cleaning may further contain (C) a thermal acid generating agent. When the film-forming composition for cleaning contains the thermal acid generating agent (C), removal of the formed film from the substrate surface is further facilitated. It is presumed that, for example, the thermal acid generating agent (C) in the formed film generates an acid by heat to promote dissociation of R¹ in the formula (i), resulting in efficient generation of the polar group, and consequently, the film would have an increased affinity to and an increased rate of dissolution in the removing liquid, leading to an achievement of the higher efficiency of removal.

The film-forming composition for cleaning may further contain (D) a surfactant. When the film-forming composition for cleaning contains the surfactant (D), removal of the formed film from the substrate surface is further facilitated. According to the film-forming composition for cleaning containing the surfactant (D), it is presumed that, for example particularly in the case of the substrate being a patterned substrate with wiring grooves (trenches), plug grooves (vias), etc., embedding properties of the film-forming composition for cleaning with respect to the substrate surface are further improved, leading to an achievement of the higher efficiency of removal.

Furthermore, the film-forming composition for cleaning may contain in addition to components (A) to (C), other optional component(s) within a range not leading to impairment of the effects of the present invention. Hereinafter, each component will be explained.

### (A) Compound

The compound (A) includes the polar group, the group (i), or a combination thereof, and has a molecular weight of no less than 300. The number of the polar group(s) and/or the group(s) (i) included in the compound (A) may be either one, or two or more. The compound (A) may be used either alone of one type, or as a mixture of two or more types thereof. When the compound (A) is a polymer, the term “molecular weight” as referred to means, o for example, a weight average molecular weight (Mw).

Polar Group

The term “polar group” as referred to means a group having at least one hetero atom. Examples of the hetero atom include an oxygen atom, a nitrogen atom, a sulfur atom, a phosphorus atom, a silicon atom, a halogen atom, and the like. Examples of the halogen atom include a fluorine atom, a chlorine atom, a bromine atom, an iodine atom, and the like. From the perspective that the polar group is enabled to have higher polarity, the hetero atom is preferably an oxygen atom, a nitrogen atom, a sulfur atom, a phosphorus atom or a halogen atom, and more preferably an oxygen atom, a nitrogen atom or a sulfur atom.

Examples of the polar group include:

groups having an active hydrogen atom such as a hydroxy group, a carboxy group, an amino group, an imino group (—NH—), a sulfo group, a sulfate group, a sulfanil group and a phosphate group;

groups having one hetero atom such as a carbonyl group, thiocarbonyl group, an ether group and a thioether group;

groups having two or more hetero atoms such as a sulfonyl group and an amide group (—CO—NH—); and the like.

In light of an improvement of the efficiency of removal of the film-forming composition for cleaning, the polar group is preferably the group having an active hydrogen atom or the group having two or more hetero atoms, more preferably a hydroxy group, a carboxy group, an amide group, an amino group, a sulfonyl group or a sulfo group, still more preferably a hydroxy group or a carboxy group, and particularly preferably a hydroxy group.

Group (i)

The group (i) is represented by the following formula (i).

—O—R¹ (i)

In the above formula (i), R¹ represents a group that is dissociated by heat or an action of an acid.

R¹ in the group (i) is dissociated by heat, or by way of an acid, which has been generated from, e.g., the (C) thermal acid generating agent described later, through a catalytic function of the acid for a dissociation reaction to cause the dissociation at a lower temperature than in the absence of the acid or at room temperature. Consequently, a polar group, for example, a carboxy group, a hydroxy group or the like, is generated from the group (i).

The lower limit of the temperature at which R¹ is dissociated is preferably 50° C., more preferably 80° C., still more preferably 110° C., and particularly preferably 140° C. The upper limit of the temperature at which R¹ is dissociated is preferably 300° C., more preferably 270° C., still more preferably 240° C., and particularly preferably 220° C. When the temperature at which R¹ is dissociated falls within the above range, in a case of carrying out a heat treatment, volatilization of the dissociated group is enabled to be further promoted, resulting in a further improvement of the efficiency of removal.

R¹ is exemplified by a secondary or tertiary monovalent hydrocarbon group, a monovalent hydrocarbon group-substituted silyl group, and the like. The term “secondary hydrocarbon group” as referred to means a hydrocarbon group in which a carbon atom serving as an atomic bonding is bonded to one hydrogen atom. The term “tertiary hydrocarbon group” as referred to means a hydrocarbon group in which a carbon atom serving as an atomic bonding is not bonded to a hydrogen atom.

Examples of the secondary hydrocarbon group include: alkyl groups such as an i-propyl group, a sec-butyl group and a sec-pentyl group;

alkenyl groups such as an ethenyl group, a 1-propen-1-yl group and a 1-buten-3-yl group;

chain hydrocarbon groups, for example alkynyl groups such as a 1-butyn-3-yl group and a 1-pentyn-4-yl group;

cycloalkyl groups such as a cyclopropyl group, a cyclobutyl group, a cyclopentyl group, a cyclohexyl group, a norbornyl group and an adamantyl group;

alicyclic hydrocarbon groups, e.g., cycloalkenyl groups such as a 1-cyclopenten-1-ylethan-1-yl group;

aromatic hydrocarbon groups, e.g., aralkyl groups such as a 1-phenylethan-1-yl group, a 1-phenylpropan-1-yl group and a 1-naphthylethan-1-yl group; and the like.

Examples of the tertiary hydrocarbon group include:

alkyl groups such as a t-butyl group, a t-pentyl group and a t-hexyl group;

alkenyl groups such as a propen-2-yl group and a 1-buten-2-yl group;

chain hydrocarbon groups, e.g., alkynyl groups such as an ethynyl group, a propyn-1-yl group and a butyn-1-yl group;

cycloalkyl groups such as a 1-methylcyclopropan-1-yl group; a 1-ethylcyclobutan-1-yl group, a 1-methylcyclopentan-1-yl group, a 1-ethylcyclohexan-1-yl group, a 2-ethylnorbornan-2-yl group and a 2-methyladamantan-2-yl group;

alicyclic hydrocarbon groups, e.g., cycloalkenyl groups such as a cyclopenten-1-yl group, a cyclohexen-1-yl group and a norbornen-2-yl group;

aryl groups such as a phenyl group, a tolyl group, a xylyl group, a naphthyl group and an anthryl group;

aromatic hydrocarbon groups, e.g., aralkyl groups such as a 2-phenylpropan-2-yl group and a 2-naphthylpropan-2-yl group; and the like.

The lower limit of the number of carbon atoms in the secondary or tertiary monovalent hydrocarbon group is preferably 2, more preferably 3, and still more preferably 4. The upper limit of the number of carbon atoms is preferably 20, more preferably 10, and still more preferably 8.

Examples of the monovalent hydrocarbon group-substituted silyl group include silyl groups in which three monovalent hydrocarbon groups are bonded, and the like. The lower limit of the number of carbon atoms in the monovalent hydrocarbon group-substituted silyl group is preferably 1, more preferably 2, and still more preferably 3. The upper limit of the number of carbon atoms is preferably 20, more preferably 10, and still more preferably 8.

From the perspective that the dissociation may take place at a more moderate temperature and that volatility of the dissociated group may increase, R¹ is preferably the tertiary monovalent hydrocarbon group or the monovalent hydrocarbon group-substituted silyl group, more preferably a tertiary chain hydrocarbon group, a tertiary alicyclic hydrocarbon group or a hydrocarbon group-substituted silyl group having at least one methyl group, still more preferably a tertiary alkyl group, a tertiary cycloalkyl group or a hydrocarbon group-substituted silyl group having at least two methyl groups, particularly preferably a t-butyl group, a t-pentyl group, a trimethylsilyl group, a t-butyldimethylsilyl group or a phenyldimethylsilyl group, and more particularly preferably a t-butyl group.

A site in the compound (A) to which the group (i) is bonded is not particularly limited, and is exemplified by a methylene chain, an aromatic ring, a carbonyl group, a thiocarbonyl group, a sulfonyl group, a sulfoxy group, a phospho group, and the like. Of these, in light of a further improvement of the efficiency of removal, the site is preferably an aromatic ring, a carbonyl group or a sulfonyl group, more preferably a carbonyl group or a sulfonyl group, and still more preferably a carbonyl group.

The compound (A) is preferably a compound including the group (i).

The lower limit of the percentage content of the group (i) with respect to the total of the polar group and the group (i) in the compound (A) is preferably 10 mol %, more preferably 30 mol %, still more preferably 50 mol %, particularly preferably 80 mol %, more particularly preferably 90 mol %, and most preferably 95 mol %. The upper limit of the percentage content of the group (i) is typically 100 mol %, and preferably 99 mol %. When the percentage content of the group (i) in the compound (A) falls within the above range, the efficiency of removal of the film-forming composition for cleaning is enabled to be further improved.

The compound (A) is exemplified by a polymer (hereinafter, may be also referred to as “(A1) polymer”), a low molecular weight compound (hereinafter, may be also referred to as “(A2) low molecular weight compound”), and the like. The term “polymer” as referred to means a compound having a repeating unit. The term “low molecular weight compound” as referred to means a compound that is not a polymer and has a molecular weight of no greater than 3,000.

### (A1) Polymer

Due to containing the polymer (A1) as the compound (A), film formability of the film-forming composition for cleaning is improved, resulting in a further improvement of the efficiency of removal.

Examples of the polymer (A1) include a ring polymer (hereinafter, may be also referred to as “(A1a) ring polymer”), a chain polymer (hereinafter, may be also referred to as “(A1b) chain polymer”), and the like. The term “ring polymer” as referred to means a polymer in which ends of the main chain bind with each other to form a ring. The term “chain polymer” as referred to means a polymer in which ends of the main chain do not bind with each other. The term “main chain” as referred to means the longest one of the atom chains of a polymer.

The lower limit of the Mw of the polymer (A1) is preferably 300, more preferably 500, still more preferably 800, and particularly preferably 1,000. The upper limit of the Mw of the polymer (A1) is preferably 50,000, more preferably 10,000, and still more preferably 5,000. It is presumed that, in the case of the substrate being a patterned substrate with wiring grooves (trenches), plug grooves (vias), etc., when the Mw of the polymer (A1) falls within the above range, the embedding properties with respect to the substrate surface are further improved, leading to an achievement of the higher efficiency of removal.

(A1a) Ring Polymer

The ring polymer (A1a) may be, for example, a calixarene, a cyclodextrin, and the like. It is presumed that, in the case of the substrate being a patterned substrate with wiring grooves (trenches), plug grooves (vias), etc., when the ring polymer (A1a) is used as the compound (A), the embedding properties of the film-forming composition for cleaning with respect to the substrate surface are improved, leading to an achievement of the still higher efficiency of removal.

(Calixarene)

The term “calixarene” as referred to means: a cyclic polymer derived from a plurality of aromatic rings to which a hydroxy group bonds, or a plurality of heteroaromatic rings to which a hydroxy group bonds, through linking to form a ring via a hydrocarbon group; or such a cyclic polymer in which a part or all of hydrogen atoms included in the hydrocarbon group, the heteroaromatic rings and the hydrocarbon group are substituted with a substituent. In other words, a calixarene typically includes a hydroxy group that is a polar group, and therefore the group (i) or the group having the group (i) may be introduced thereinto by means of the hydroxy group.

The calixarene including a hydroxy group that is a polar group may be obtained through, for example, a condensation reaction between a phenolic hydroxy group-containing compound represented by the following formula (1) and an aldehyde. The aldehyde is exemplified by a compound represented by the following formula (2). It is to be noted that, when the compound represented by the following formula (2) is formaldehyde, paraformaldehyde may be used; and when the compound represented by the following formula (2) is acetaldehyde, paraldehyde may be used.

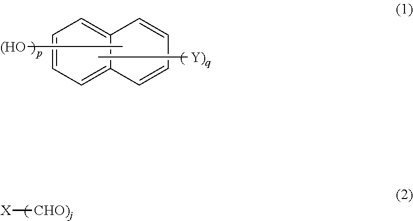

In the above formula (1), Y represents a hydrocarbon group having 1 to 10 carbon atoms; q is an integer of 0 to 7 and p is an integer of 1 to 4, wherein 1 ≤p+q≤6; and k is 0 or 1.

In the above formula (2), X represents a substituted or unsubstituted hydrocarbon group having a valency of j and having 1 to 30 carbon atoms, or a hydrogen atom; and j is 1 or 2.

The hydrocarbon group having 1 to 10 carbon atoms represented by Y is exemplified by, among the monovalent hydrocarbon groups exemplified as R¹, those having 1 to 10 carbon atoms. Of these, a hydrocarbon group having 1 to 5 carbon atoms is preferred, and an alkyl group having 1 to 5 carbon atoms is more preferred.

Preferably, p is an integer of 1 to 3, and more preferably 2 or 3. Preferably, q is an integer of 0 to 2, more preferably 0 or 1, and still more preferably 0.

The hydrocarbon group having a valency of j and having 1 to 30 carbon atoms represented by X is exemplified by: in the case of j being 1, the monovalent hydrocarbon group exemplified as R¹ and the like; and in the case of j being 2, a group obtained by removing one hydrogen atom from the monovalent hydrocarbon group in the case of j being 1, and the like.

Examples of the substituent for the hydrocarbon group include a hydroxy group, a halogen atom, an oxo group (═O), and the like.

Preferably, j is 1. X is preferably a hydrogen atom, a chain hydrocarbon group, or a substituted or unsubstituted aromatic hydrocarbon group, more preferably a hydrogen atom, a monovalent chain hydrocarbon group, or a substituted or unsubstituted monovalent aromatic hydrocarbon group, still more preferably a hydrogen atom, an alkyl group or a hydroxy-substituted phenyl group, and particularly preferably a hydrogen atom, a methyl group, a 4-hydroxyphenyl group or a 3,4-dihydroxyphenyl group.

A calixarene including the group (i) may be obtained by substituting a hydrogen atom in the hydroxy group included in the calixarene obtained as described above, with the group exemplified as R¹ or a group including the group (i). A substituent for a hydrogen atom in the hydroxy group included in the calixarene is preferably the group having the group (i), more preferably a carbonylalkyl group to which the group (i) bonds, still more preferably a carbonylmethyl group to which the group (i) bonds, and particularly preferably a t-butoxycarbonylmethyl group.

The calixarene is exemplified by a compound represented by the following formula (3), a compound represented by the following formula (4), a s compound represented by the following formula (5), and the like.

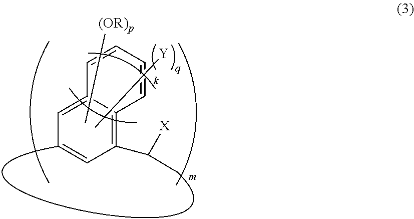

In the above formula (3), R represents a hydrogen atom or a monovalent organic group having 1 to 30 carbon atoms; m is an integer of 4 to 12; Y, k, p and q are as defined in the above formula (1); and X is as defined in the above formula (2) in the case of j being 1.

In light of a further improvement of the embedding properties of the film-forming composition for cleaning with respect to the patterned substrate surface, the upper limit of m is preferably 8, more preferably 6, and still more preferably 4.

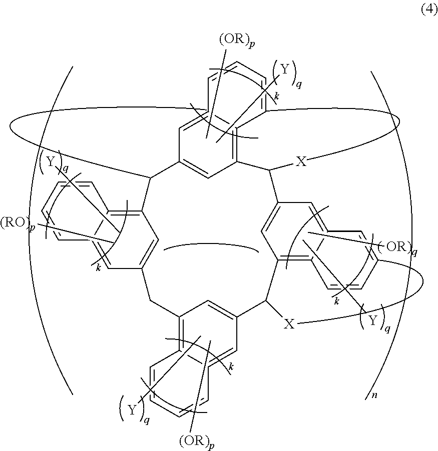

In the above formula (4), R represents a hydrogen atom or a monovalent organic group having 1 to 30 carbon atoms; n is 2 or 3; Y, k, p and q are as defined in the above formula (1); and X is as defined in the above formula (2) in the case of j being 2.

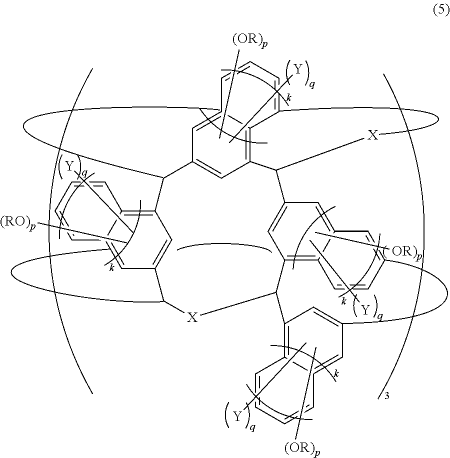

In the above formula (5), R represents a hydrogen atom or a monovalent organic group having 1 to 30 carbon atoms; Y, k, p and q are as defined in the above formula (1); and X is as defined in the above formula (2) in the case of j being 2.

The calixarene is also exemplified by compounds represented by the following formulae, and the like.

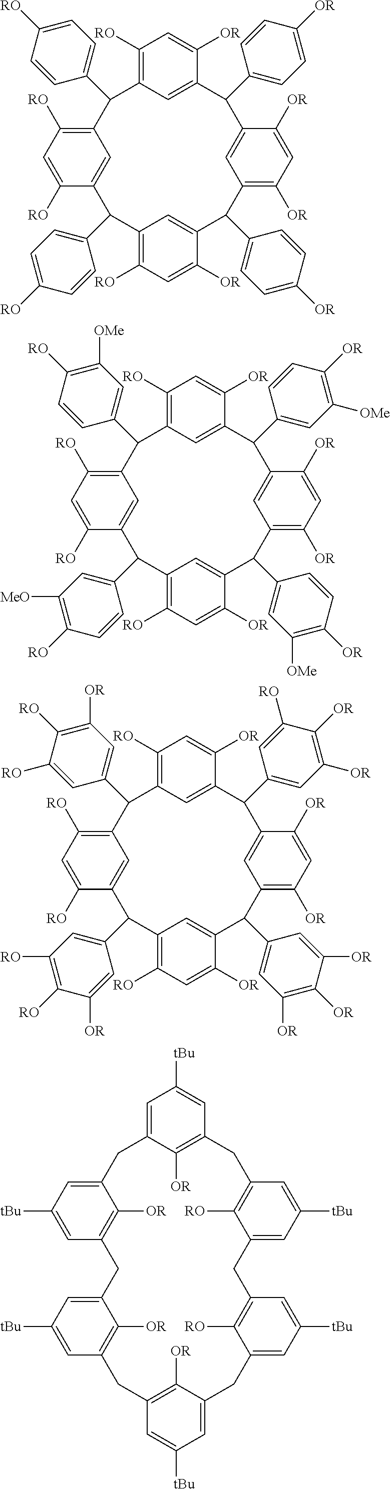

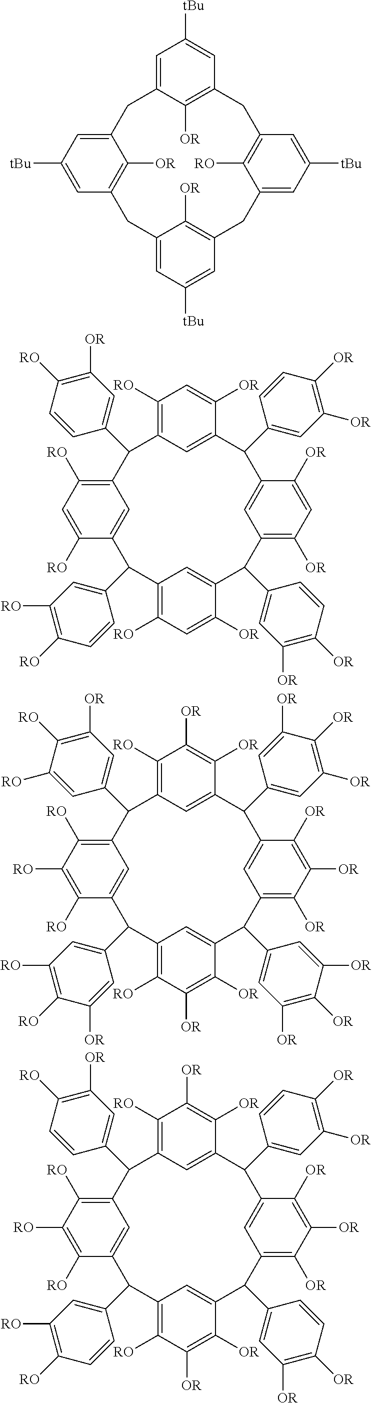

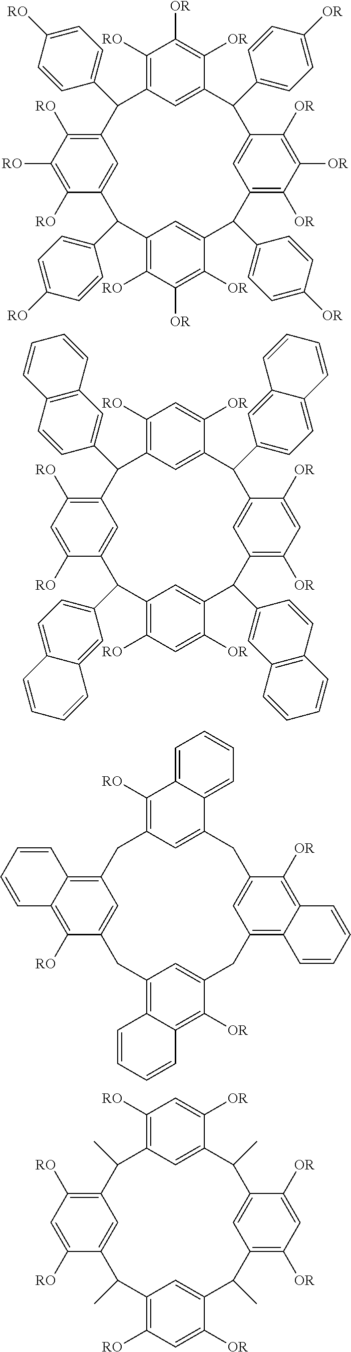

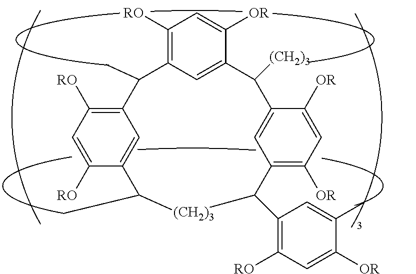

In the above formula, R represents a hydrogen atom or a monovalent organic group having 1 to 30 carbon atoms.

(Cyclodextrin)

The term “cyclodextrin” as referred to means a polymer in which D-glucose forms a ring structure through an a1,4-bond. A cyclodextrin includes a hydroxy group that is a polar group, and therefore the group (i) or the group having the group (i) may be introduced thereinto by means of the hydroxy group.

The cyclodextrin is exemplified by an α-cyclodextrin, a β-cyclodextrin, a γ-cyclodextrin, and the like. Of these, in light of a further improvement of the embedding properties with respect to the patterned substrate, an α-cyclodextrin is preferred.

The lower limit of the Mw of the ring polymer (A1a) is preferably 300, more preferably 350, still more preferably 400, particularly preferably 500, and more particularly preferably 600. The upper limit of the Mw of the ring polymer (A1a) is preferably 3,000, more preferably 2,500, still more preferably 2,000, and particularly preferably 1,500. It is presumed that, in the case of the substrate being a patterned substrate with wiring grooves (trenches), plug grooves (vias), etc., when the Mw of the ring polymer (A1a) falls within the above range, the embedding properties with respect to the substrate surface are further improved, leading to an achievement of the higher efficiency of removal.

(A1b) Chain Polymer

The chain polymer (A1b) may be, for example: addition polymers such as an acrylic resin, a styrene resin and a vinyl alcohol resin; condensation polymers such as a phenol resin; and the like.

(Acrylic Resin)

The term “acrylic resin” as referred to means a polymer having a repeating unit derived from acrylic acid, an acrylic acid ester or a derivative thereof, i.e., a polymer having as a repeating unit, —[C(R^{A})(R^{B})—C(R^{C})(COOR^{D})]—, wherein R^{A}, R^{B} and R^{C} each independently represent a hydrogen atom or an alkyl group having 1 to 10 carbon atoms; and R^{D} represents a hydrogen atom or a monovalent organic group having 1 to 30 carbon atoms. The organic group which may be represented by R^{D} has the polar group and/or the group (i).

A monomer having the polar group constituting the acrylic resin is exemplified by:

hydroxy group-containing esters such as hydroxyethyl (meth)acrylate and hydroxyethyl crotonate;

carboxy group-containing esters such as (meth)acrylic acid and (iso)crotonic acid;

amide group-containing esters such as (meth)acrylamide and (iso)crotonamide;

amino group-containing esters such as aminoethyl (meth)acrylate and aminoethyl (iso)crotonate;

sulfonyl group-containing esters such as methylsulfonylethyl (meth)acrylate and methylsulfonylethyl (iso)crotonate;

sulfo group-containing esters such as sulfoethyl (meth)acrylate and sulfoethyl (iso)crotonate; and the like.

A monomer having the group (i) constituting the acrylic resin is exemplified by:

tertiary alkyl esters such as t-butyl (meth)acrylate, t-amyl (meth)acrylate, t-butyl (iso)crotonate and t-amyl (iso)crotonate; silyl esters such as trimethylsilyl (meth)acrylate, t-butyldimethylsilyl (meth)acrylate and phenyldimethylsilyl (meth)acrylate; and the like.

(Styrene Resin)

The term “styrene resin” as referred to means a polymer having a repeating unit derived from a styrene or a substituted styrene, i.e., a polymer having as a repeating unit, —[C(R^{A})(R^{B})—C(R^{C})(Ar^{D}—R^{E})]—, wherein R^{A}, R^{B} and R^{C} each independently represent a hydrogen atom or an alkyl group having 1 to 10 carbon atoms; Ar^{D} represents an arenediyl group having 6 to 20 carbon atoms; and R^{E} represents a hydrogen atom or a monovalent organic group having 1 to 30 carbon atoms. The organic group which may be represented by R^{E} has the polar group and/or the group (i).

A monomer having the polar group constituting the styrene resin is exemplified by:

hydroxy group-containing aromatic vinyl compounds such as hydroxystyrene, hydroxyvinylnaphthalene, hydroxymethylstyrene and hydroxymethylvinylnaphthalene;

carboxy group-containing aromatic vinyl compounds such as carboxystyrene and carboxyvinylnaphthalene;

sulfonyl group-containing aromatic vinyl compounds such as methyl sulfonylstyrene and methylsulfonylvinylnaphthalene;

sulfo group-containing aromatic vinyl compounds such as sulfostyrene and sulfovinylnaphthalene; and the like.

A monomer having the group (i) constituting the styrene resin is exemplified by:

tertiary alkyl group-containing aromatic vinyl compounds such as t-butoxystyrene, t-amyloxystyrene, t-butoxyvinylnaphthalene and t-amyl oxyvinylnaphthalene;

silyloxy group-containing aromatic vinyl compounds such as trimethylsilyloxystyrene, t-butyldimethylsilyloxystyrene, phenyldimethylsilyloxystyrene, trimethylsilyloxyvinylnaphthalene, t-butyldimethylsilyloxyvinylnaphthalene and phenyldimethylsilyloxyvinylnaphthalene; and the like.

(Vinyl Alcohol Resin)

The term “vinyl alcohol resin” as referred to means a polymer having as a repeating unit, —[C(R^{F})(R^{G})—C(R^{H})(OR^{I})]—, wherein R^{F}, R^{G} and R^{H} each independently represent a hydrogen atom or an alkyl group having 1 to 10 carbon atoms; and R¹ represents a hydrogen atom or a monovalent organic group having 1 to 30 carbon atoms. The organic group which may be represented by R¹ has the polar group and/or the group (i).

The vinyl alcohol resin in which R¹ is a hydrogen atom has a hydroxy group as the polar group. Such a vinyl alcohol resin may be obtained by hydrolysis of a polymer formed from carboxylic alkenyl ester as a monomer.

A monomer having the group (i) constituting the vinyl alcohol resin is exemplified by:

tertiary alkenyloxycarboxylic acid esters such as t-butyl vinyloxyacetate, t-amyl vinyloxyacetate, t-butyl 1-propenyloxyacetate and t-amyl 1-propenyloxyacetate;

alkenyloxycarboxylic acid silyl esters such as trimethylsilyl vinyloxyacetate, t-butyldimethylsilyl vinyloxyacetate, phenyldimethylsilyl vinyloxyacetate, trimethylsilyl 1-propenyloxyacetate, t-butyldimethylsilyl 1-propenyloxyacetate and phenyldimethylsilyl 1-propenyloxyacetate; and the like.

(Phenol Resin)

The term “phenol resin” as referred to means a polymer obtained through a reaction of a compound having a phenolic hydroxyl group with an aldehyde, a divinyl compound or the like, in the presence of an acid catalyst, an alkaline catalyst or the like. The phenol resin has a repeating unit derived from the compound having a phenolic hydroxyl group and the aldehyde or the divinyl compound. The phenol resin typically has a hydroxy group that is a polar group. In addition, the polar group and/or the group (i) may be introduced into the phenol resin through substitution of a hydrogen atom in the hydroxy group.

The compound having the phenolic hydroxyl group is exemplified by:

monophenols such as phenol, cresol, xylenol, p-t-butylphenol, p-octylphenol, 1-naphthol and 2-naphthol;

diphenols such as resorcinol, bisphenol-A, 1,5-dihydroxynaphthalene, 2,7-dihydroxynaphthalene and fluorene-9,9-diphenol; and the like.

The aldehyde is exemplified by formaldehyde, paraformaldehyde, trioxane, acetaldehyde, paraldehyde, propionaldehyde, benzaldehyde, and the like. The divinyl compound is exemplified by divinylbenzene, dicyclopentadiene, tetrahydroindene, 4-vinylcyclohexene, 5-vinylnorborn-2-ene, α-pinene, limonene, 5-vinylnorbornadiene, and the like.

The chain polymer (A1b) may also include a repeating unit other than the repeating unit having the polar group and/or the group (i).

The lower limit of the proportion of the repeating unit having the polar group and/or the group (i) included in the chain polymer (A1b) is preferably 10 mol %, more preferably 50 mol %, still more preferably 70 mol %, particularly preferably 90 mol %, and more particularly preferably 100 mol % with respect to the total repeating units constituting the chain polymer (A1b). When the proportion of the repeating unit having the polar group and/or the group (i) included in the chain polymer (A1b) falls within the above range, the efficiency of removal of the film-forming composition for cleaning is enabled to be further improved.

The lower limit of the Mw of the chain polymer (A1b) is preferably 500, more preferably 800, and still more preferably 1,000. The upper limit of the Mw of the chain polymer (A1b) is preferably 50,000, more preferably 10,000, still more preferably 5,000, and particularly preferably 3,000. It is presumed that, in the case of the substrate being a patterned substrate with wiring grooves (trenches), plug grooves (vias), etc., when the Mw of the chain polymer (A1b) falls within the above range, the embedding properties with respect to the substrate surface are further improved, leading to an achievement of the still higher efficiency of removal.

### (A2) Low Molecular Weight Compound

The term “low molecular weight compound (A2)” as referred to means a compound that is not a polymer and has a molecular weight of no greater than 3,000. It is presumed that, in the case of the substrate being a patterned substrate with wiring grooves (trenches), plug grooves (vias), etc., when the film-forming composition for cleaning contains the low molecular weight compound (A2) as the compound (A), the embedding properties with respect to the substrate surface are further improved, leading to an achievement of the higher efficiency of removal.

The lower limit of the molecular weight of the low molecular weight compound (A2) is preferably 350, more preferably 400, still more preferably 500, and particularly preferably 600. The upper limit of the molecular weight of the low molecular weight compound (A2) is preferably 2,000, more preferably 1,500, still more preferably 1,200, and particularly preferably 1,000. It is presumed that, when the molecular weight of the low molecular weight compound (A2) falls within the above range, the film formability of the film-forming composition for cleaning is further improved, leading to an achievement of the higher efficiency of removal.

The lower limit of the number of the polar group(s) and the group(s) (i) in the low molecular weight compound (A2) is preferably 2, and more preferably 3. The upper limit of the number is preferably 10, and more preferably 6. It is presumed that, when the number of the polar group(s) and the group(s) (i) in the low molecular weight compound (A2) falls within the above range, the film formability of the film-forming composition for cleaning is further improved, leading to an achievement of the still higher efficiency of removal.

The low molecular weight compound (A2) is exemplified by a compound in which the polar group, the group (i), or a group having any of these groups bonds to a ring such as an aromatic ring, an aromatic heterocyclic ring, an alicyclic ring or an aliphatic heterocyclic ring, and the like.

Examples of the low molecular weight compound (A2) having the polar group include:

polar group-containing aromatic compounds such as tri(hydroxybutyl) trimesate and 1,2,3-tri(hydroxybutoxy)benzene; and

monosaccharides such as a pentose e.g., ribose, deoxy ribose, etc., a hexose e.g., glucose, fructose, galactose, mannose, etc., and the like.

Examples of the low molecular weight compound (A2) having the group (i) include:

aromatic compounds having the group (i) such as tri-t-butyl trimesate and 1,2,3-tri(t-butoxycarbonylmethoxy)benzene;

a compound in which a part or all of hydrogen atoms in the hydroxy group included in the monosaccharide are substituted with the group having the group (i); and the like.

The lower limit of the content of the compound (A) is preferably 0.1% by mass, more preferably 0.5% by mass, and still more preferably 1% by mass. The upper limit of the content is preferably 50% by mass, more preferably 30% by mass, and still more preferably 15% by mass.

The lower limit of the content of the compound (A) with respect to the total solid content in the film-foiming composition for cleaning is preferably 30% by mass, more preferably 40% by mass, and still more preferably 50% by mass. The upper limit of the content is preferably 100% by mass, more preferably 98% by mass, and still more preferably 96% by mass. The “total solid content” as referred to means the sum of the components other than the solvent (B).

When the content of the compound (A) falls within the above range, removability of the film from the substrate surface can be further enhanced.

### (B) Solvent

The solvent (B) may be any one as long as it can dissolve or disperse the compound (A), and a solvent that can dissolve the compound (A) is preferred. In addition, in the case of the film-forming composition for cleaning containing the thermal acid generating agent (C), a solvent that can dissolve the thermal acid generating agent (C) is preferred as the solvent (B). Furthermore, in the case of the film-forming composition for cleaning containing the surfactant (D) added thereto, a solvent that can dissolve the surfactant (D) is preferred as the solvent (B).

The solvent (B) is exemplified by: polar organic solvents such as an alcohol solvent, an ether solvent, a ketone solvent, an amide solvent and an ester solvent; hydrocarbon solvents; water; and the like.

Examples of the alcohol solvent include: monohydric alcohols having 1 to 18 carbon atoms such as ethanol, isopropyl alcohol, amyl alcohol, 4-methyl-2-pentanol, cyclohexanol, 3,3,5-trimethylcyclohexanol, furfuryl alcohol, benzyl alcohol and diacetone alcohol; dihydric alcohols having 2 to 12 carbon atoms such as ethylene glycol, propylene glycol, diethylene glycol, dipropylene glycol, triethylene glycol and tripropylene glycol; and partial ethers of the same.

Examples of the ether solvent include: dialkyl ether solvents such as diethyl ether, dipropyl ether, dibutyl ether and diisoamyl ether; cyclic ether solvents such as tetrahydrofuran and tetrahydropyran; aromatic ring-containing ether solvents such as diphenyl ether and anisole; and the like.

Examples of the ketone solvent include: chain ketone solvents such as acetone, methyl ethyl ketone, methyl n-propyl ketone, methyl n-butyl ketone, diethyl ketone, methyl iso-butyl ketone, 2-heptanone, ethyl n-butyl ketone, methyl n-hexyl ketone, di-iso-butyl ketone and trimethyl nonanone; cyclic ketone solvents such as cyclopentanone, cyclohexanone, cycloheptanone, cyclooctanone and methylcyclohexanone; 2,4-pentanedione; acetonylacetone; acetophenone; and the like.

Examples of the amide solvent include: cyclic amide solvents such as N,N′-dimethylimidazolidinone and N-methylpyrrolidone; chain amide solvents such as N-methylformamide, N,N-dimethylformamide, N,N-diethylformamide, acetamide, N-methylacetamide, N,N-dimethylacetamide and N-methylpropionamide; and the like.

Examples of the ester solvent include: monohydric alcohol carboxylate solvents such as ethyl acetate, butyl acetate, benzyl acetate, cyclohexyl acetate, ethyl lactate and ethyl 3-methoxypropionate; polyhydric alcohol partial ether carboxylate solvents such as monocarboxylates of an alkylene glycol monoalkyl ether, and monocarboxylates of a dialkylene glycol monoalkyl ether; cyclic ester solvents such as butyrolactone; carbonate solvents such as diethyl carbonate; polyhydric carboxylic acid alkyl ester solvents such as diethyl oxalate and diethyl phthalate.

Examples of the hydrocarbon solvent include: aliphatic hydrocarbon solvents such as n-pentane, iso-pentane, n-hexane, iso-hexane, n-heptane, iso-heptane, 2,2,4-trimethylpentane, n-octane, iso-octane, cyclohexane and methylcyclohexane; aromatic hydrocarbon solvents such as benzene, toluene, xylene, mesitylene, ethylbenzene, trimethylbenzene, methylethylbenzene, n-propylbenzene, iso-propylbenzene, diethylbenzene, iso-butylbenzene, triethylbenzene, di-iso-propylbenzene and n-amylnaphthalene; and the like.

Of these, the polar organic solvents and water are preferred. The polar organic solvent is preferably an alcohol, an ether of a dihydric alcohol, an alkyl ether solvent, of a polyhydric alcohol a cyclic ketone solvent, a monohydric alcohol carboxylate solvent, a cyclic ester solvent, a polyhydric alcohol partial ether carboxylate solvent or a polyhydric alcohol alkyl ether solvent, more preferably an alcohol or a polyhydric alcohol alkyl ether, and still more preferably 4-methyl-2-pentanol, diisoamyl ether, propylene glycol monoethyl ether, ethyl lactate, methyl 3-methoxypropionate, butyrolactone or propylene glycol monomethyl ether acetate.

In the case of the solvent (B) containing water, the upper limit of the percentage content of water in the solvent (B) is preferably 20% by mass, more preferably 10% by mass, still more preferably 5% by mass, and particularly preferably 2% by mass. When the percentage content of water in the solvent (A) is no greater than the upper limit, solubility of the compound (A) in the solvent can be improved and the film-forming composition for cleaning can exhibit proper wet spreadability on substrate surfaces, and as a result, a cleaning property by the film-forming composition for cleaning can be improved. The lower limit of the percentage content of water is preferably 0.1% by mass, more preferably 0.5% by mass, and still more preferably 1% by mass.

The lower limit of the content of the solvent (B) is preferably 50% by mass, more preferably 80% by mass, and still more preferably 90% by mass. The upper limit of the content is preferably 99.9% by mass, more preferably 99.5% by mass, and still more preferably 99.0% by mass. When the content of the solvent (B) falls within the range of from the lower limit to the upper limit, the cleaning property of the film-forming composition for cleaning on substrates can be further improved. The film-forming composition for cleaning may contain either one, or two or more types of the solvent (B).

### (C) Thermal Acid Generating Agent

The film-forming composition for cleaning may contain the thermal acid generating agent (C). The thermal acid generating agent (C) generates an acid by heat. It is presumed that, due to adding the thermal acid generating agent (C), dissociation of R¹ in the formula (i) is promoted, resulting in efficient generation of the polar group, and consequently, the film-forming composition for cleaning would have an increased affinity to and an increased rate of dissolution in the removing liquid, leading to an achievement of the higher efficiency of removal.

The thermal acid generating agent (C) is exemplified by 2,4,4,6-tetrabromocyclohexadienone, benzointosylate, 2-nitrobenzyl tosylate, other alkyl esters of an organic sulfonic acid, and the like. The thermal acid generating agent (C) may also be exemplified by onium salts such as a sulfonium salt, an iodonium salt, a benzothiazonium salt, an ammonium salt and a phosphonium salt. Specific examples of the thermal acid generating agent (C) include: salts of a fluorinated metal compound such as 4-acetoxyphenyldimethylsulfonium hexafluoroarsenate, benzyl-4-hydroxyphenylmethylsulfonium hexafluoroantimonate, 4-acetoxyphenylbenzylmethylsulfonium hexafluoroantimonate, dibenzyl-4-hydroxyphenylsulfonium hexafluoroantimonate, 4-acetoxyphenylbenzylsulfonium hexafluoroantimonate and 3-benzylbenzothiazolium hexafluoroantimonate; sulfonimide compounds such as a compound represented by the following formula (6-1); salts of an organic sulfonic acid such as bis(4-t-butylphenyl)iodonium nonafluoro-n-butanesulfonate, triethylammonium nonafluoro-n-butanesulfonate and a compound represented by the following formula (6-2); and the like.

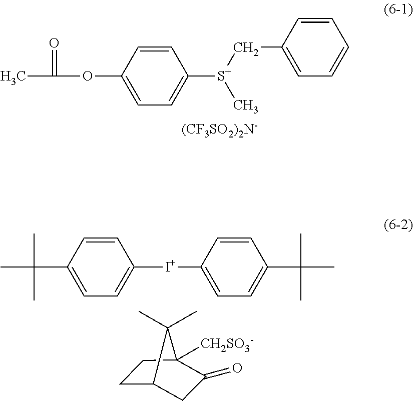

Of the onium salts, the thermal acid generating agent (C) is preferably the iodonium salt or the ammonium salt of the organic sulfonic acid, more preferably the ammonium salt of the organic sulfonic acid, and particularly preferably a compound represented by the following formula (6-3).

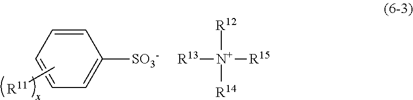

In the above formula (6-3), R¹¹ represents an alkyl group having 1 to 15 carbon atoms; R¹² to R¹⁴ each independently represent an alkyl group having 1 to 10 carbon atoms; R¹⁵ represents a hydroxyalkyl group having 1 to 5 carbon atoms; and x is an integer of 1 to 3, wherein in a case where x is no less than 2, a plurality of R¹¹s may be identical or different.

The number of carbon atoms in the alkyl group represented by R¹¹ is preferably 3 to 15, and more preferably 3 to 12. The alkyl group may be either linear or branched, and preferably linear. The alkyl group is particularly preferably a dodecyl group. In the above formula (6-3), x is preferably 1. It is to be noted that, although a binding site of R¹¹ on the benzene ring is not particularly limited, in light of availability and the like, it is preferred that R¹¹ bonds at least to the para position to the binding site of —SO₃⁻.

The number of carbon atoms in the alkyl group represented by any one of R¹² to R¹⁴ is preferably 1 to 5. The alkyl group may be either linear or branched. The alkyl group is preferably a methyl group. The hydroxyalkyl group represented by R¹⁵ may be either linear or branched, and preferably linear. Of these, a group represented by —(CH₂)mOH (wherein, m is an integer of 1 to 4) is preferred, and —CH₂CH₂OH is particularly preferred.

In the case of the film-forming composition for cleaning containing the thermal acid generating agent (C), the lower limit of the content of the thermal acid generating agent (C) is preferably 0.1 parts by mass, more preferably 0.5 parts by mass, still more preferably 1 part by mass, and particularly preferably 3 parts by mass with respect to 100 parts by mass of the compound (A). The upper limit of the content is preferably 20 parts by mass, more preferably 10 parts by mass, still more preferably 7 parts by mass, and particularly preferably 5 parts by mass. It is presumed that, when the content of the thermal acid generating agent (C) falls within the above range, dissociation of R¹ in the formula (i) is promoted, resulting in efficient generation of the polar group, and consequently, the film-forming composition for cleaning would have an increased affinity to and an increased rate of dissolution in the removing liquid, leading to an achievement of the higher efficiency of removal. The thermal acid generating agent (C) may be used either of one type alone, or at least two types thereof may be used in combination.

### (D) Surfactant

Examples of the surfactant (D) include nonionic surfactants such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate and polyethylene glycol distearate, and the like.

In the case of the film-forming composition for cleaning containing the surfactant (D), the lower limit of the content of the surfactant (D) in the film-forming composition for cleaning is preferably 0.001% by mass, and more preferably 0.01% by mass. The upper limit of the content is preferably 2% by mass, more preferably 1% by mass, and still more preferably 0.1% by mass,

### Other Optional Component

The film-forming composition for cleaning may contain other optional component in addition to the components (A) to (D). The other optional component is exemplified by a crosslinking agent, a crosslinking accelerator, and the like. The film-forming composition for cleaning may contain either one, or two or more types of the other optional component. In the case of the film-forming composition for cleaning containing the other optional component, the upper limit of the content of the other optional component is preferably 20 parts by mass, and more preferably 10 parts by mass, with respect to 100 parts by mass of the component (A). The lower limit of the content is, for example, 0.1 parts by mass.

### Preparation of Composition for Forming Film for Use in Cleaning

The film-forming composition for cleaning may be prepared, for example, by mixing the compound (A) and the solvent (B), as well as the thermal acid generating agent (C), the surfactant (D) and the other optional component as needed, at a certain ratio, preferably followed by filtering a mixture thus obtained through a filter having a pore size of about 0.1 to 5 μm or the like. The lower limit of the solid content concentration of the film-forming composition for cleaning is preferably 0.1% by mass, more preferably 0.5% by mass, still more preferably 1% by mass, and particularly preferably 2% by mass. The upper limit of the solid content concentration is preferably 50% by mass, more preferably 30% by mass, still more preferably 20% by mass, and particularly preferably 15% by mass.

### Cleaning Method for Semiconductor Substrate

The cleaning method for a semiconductor substrate includes: applying the film-forming composition for cleaning on a surface of the semiconductor substrate to form a film (hereinafter, may be also referred to as “film (I)”) for cleaning the semiconductor substrate (hereinafter, may be also referred to as “film-forming step”); and removing the film (I) from the substrate (hereinafter, may be also referred to as “removing step”).

By forming the film (I) on the substrate surface using the film-forming composition for cleaning, unwanted substances on the substrate surface can be efficiently removed. Furthermore, the formed film (I) can be easily removed from the substrate surface. Thus, the film-forming composition for cleaning is applicable to substrates formed from a variety of materials. Examples of the substrate to which the film-forming composition for cleaning is applicable include metal or metalloid substrates such as silicon substrates, aluminum substrates, nickel substrates, chromium substrates, molybdenum substrates, tungsten substrates, copper substrates, tantalum substrates and titanium substrates; ceramic substrates such as silicon nitride substrate, alumina substrates, silicon dioxide substrates, tantalum nitride substrates and titanium nitride substrates; and the like. Of these, silicon substrates, silicon nitride substrates and titanium nitride substrates are preferred, and silicon substrates are more preferred.

One example of the method of application of the film-forming composition for cleaning according to the embodiment of the present invention to cleaning of a substrate is explained in more detail with reference to drawings.

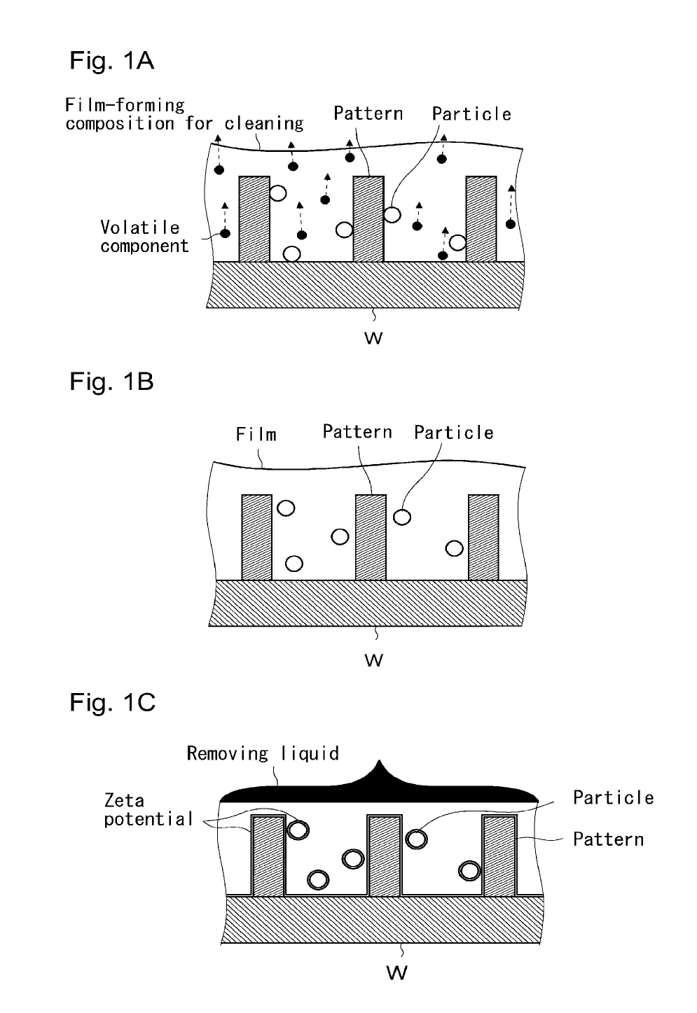

As shown in FIG. 1A, in this application example, the aforementioned film-forming composition for cleaning is used as a treatment liquid for forming a film (I) on a wafer W. First, the film-forming step is carried out. More specifically, the film-forming composition for cleaning is applied on the wafer

W to form a coating film of the film-forming composition for cleaning. The applying procedure may involve, for example, spin coating, cast coating, roll coating, and the like. Next, the coating film is subjected to heating (baking) and/or vacuum to efficiently remove a part or all of the solvent contained in the coating film, thereby enabling solidification and/or hardening of the solid content contained in the coating film to be promoted. The term “solidification” as referred to herein means giving a state of solid, and “hardening” as referred to means an increase of the molecular weight through linking of the molecules (by, for example, crosslinking, polymerization and the like). The film (I) is thus formed. In this procedure, the particles attached to the pattern and the like are incorporated into the film and efficiently drawn away from the pattern and the like (see FIG. 1B). The lower limit of the temperature for the heating for the solidification and/or hardening is preferably 50° C., more preferably 80° C., still more preferably 110° C., and particularly preferably 140° C. The upper limit of the temperature for the heating is preferably 300° C., more preferably 270° C., still more preferably 240° C., and particularly preferably 220° C. The lower limit of the time period of the heating is preferably 5 sec, more preferably 10 sec, and still more preferably 30 sec. The upper limit of the time period of the heating is preferably 10 min, more preferably 5 min, and still more preferably 2 min. When the temperature and the time period of the heating fall within the above ranges, volatilization of the group dissociated by heat treatment is enabled to be further promoted, resulting in a further improvement of the efficiency of removal. The lower limit of the average thickness of the film (I) formed is preferably 10 nm, and more preferably 20 nm. The upper limit of the average thickness is preferably 1,000 nm, and more preferably 500 nm.

Next, the removing step is carried out. More specifically, a removing liquid that dissolves the film (I) is supplied onto the film (I), whereby the film (I) is entirely removed from the wafer W. As a result, the particles are removed from the wafer W together with the film (I). As the removing liquid, water, an organic solvent, an aqueous alkaline solution or the like may be used, and the removing liquid is preferably water or an aqueous alkaline solution, and more preferably an aqueous alkaline solution. As the aqueous alkaline solution: an alkaline developer solution; a mixture of an aqueous alkaline solution, an aqueous hydrogen peroxide solution and water; or the like may be used. The alkaline developer solution may be a well-known alkaline developer solution. Specific examples of the alkaline developer solution include aqueous solutions containing at least one of ammonia, tetramethylammonium hydroxide (TMAH) and choline, and the like. As the organic solvent, for example, a thinner, isopropyl alcohol (IPA), 4-methyl-2-pentanol (MIBC), toluene, an acetic acid ester, an alcohol, a glycol (propylene glycol monomethyl ether, etc.) or the like may be used. Also, the removal of the film (I) may be carried out sequentially through using different types of the removing liquids, e.g., by supplying water as the removing liquid first on the film, and then supplying an alkaline developer solution. By sequentially using different types of the removing liquids, film removability can be further improved.

When the removing liquid such as an alkaline developer solution or the like is supplied, zeta potentials having identical polarity (in this case, minus) are generated on the wafer W, the pattern surface and the particle surface, as shown in FIG. 1C. The particles drawn away from the wafer W and the like are charged with a zeta potential having identical polarity to that of the wafer W and the like, leading to resilience with the wafer W and the like. Accordingly, reattachment of the particle to the wafer W and the like can be prevented.

Thus, in the present application example, the particles can be removed with a weaker force as compared with conventional removal of the particles by way of physical force, and therefore, pattern collapse can be inhibited. In addition, since the particles are removed without utilizing a chemical action, erosion of the base film due to an etching action, etc., can be also inhibited. Furthermore, smaller particles, and particles embedded into gaps of the pattern can be also easily removed, which involve difficulty in the removal according to a cleaning method for substrates carried out using a physical force.

The film-forming composition for cleaning supplied onto the wafer W is finally removed completely from the wafer W. Therefore, the wafer W after the cleaning will have a state as before applying the film-forming composition for cleaning, more specifically, a state in which the circuit-forming face is exposed.

The cleaning method may be carried out by using well-known various apparatuses and skill methods. A suitable apparatus is exemplified by an apparatus for cleaning a substrate disclosed in Japanese Unexamined Patent Application, Publication No. 2014-99583.

### EXAMPLES

Hereinafter, the present invention is explained in detail by way of Examples, but the present invention is not limited to these Examples. Measuring methods for physical properties in connection with the Examples are shown below.
Weight Average Molecular Weight (Mw) and Number Average Molecular Weight (Mn)

The weight average molecular weight (Mw) and the number average molecular weight (Mn) of a polymer obtained were determined by gel permeation chromatography (GPC) using GPC columns (G2000 HXL×2, G3000 HXL×1 and G4000 HXL×1) manufactured by Tosoh Corporation, a differential refractometer as a detector, and mono-dispersed polystyrene as a standard, under analytical conditions involving a flow rate of 1.0 mL/min, an elution solvent of tetrahydrofuran, a sample concentration of 1.0% by mass, an amount of an injected sample of 100 μL, and a column temperature of 40° C. In addition, the dispersity index (Mw/Mn) was calculated based on the results of the determination of the Mw and the Mn.

### Synthesis of Polymer (A)

The polymer (A) was synthesized according to the following procedure.

### Production Example 1

To a 1,000-mL three-neck flask equipped with a thermometer, a condenser and a magnetic stirrer were added 125.0 g (1.14 mol) of resorcinol, 100 g of ethanol, 42.1 g of concentrated hydrochloric acid and 126.6 g of water in a nitrogen atmosphere, and dissolution was attained at room temperature. The resulting solution was heated to 90° C. To the resulting solution thus heated, 50.0 g (0.38 mol) of paraldehyde was added dropwise over 15 min, and then a reaction was allowed for 6 hrs. After the reaction, the flask was cooled until the solution temperature reached room temperature. Thereafter, the solid precipitated was collected by filtration to remove the ethanol solution. Washing with a flowing mixed solution of methanol and water (each 500 g) was carried out, followed by drying at 60° C. overnight under reduced pressure, whereby a light yellow solid in a powdery state was obtained as a polymer (A1a-1a) (amount: 93.3 g; yield: 60%). The polymer (A1a-1a) is a compound represented by the following formula (A1a-1), in which all R^{X}s are hydrogen atoms.

Next, in a 500-mL three-neck flask equipped with a thermometer, a condenser and a magnetic stirrer were mixed 200 mL of N,N-dimethylacetamide, 27.2 g of potassium carbonate, and 10.0 g of the polymer (A1a-1a) synthesized as above in a nitrogen atmosphere, and dissolution was attained with stirring by the magnetic stirrer. The resulting solution was heated to 80° C. To the resulting solution thus heated, 39.4 g of tert-butyl bromoacetate was added dropwise over 30 min, and then a reaction was allowed for 6 hrs. After the reaction, the reaction solution was added to 2 L of water to which 14 mL of acetic acid was added. The supernatant liquid was removed, then the residual highly viscous matter was dissolved in a minimum amount of acetone, and the solution was charged into 500 mL of water to permit reprecipitation. The highly viscous matter thus obtained was dried at 60° C. overnight under reduced pressure, whereby 10.9 g of a polymer (A1a-1) represented by the following formula (A1a-1) was obtained (yield: 60%). The polymer (A1a-1) obtained had the Mw of 1,200. The ¹H-NMR analysis revealed that a protection rate in the polymer (A1a-1) (a rate of substitution of hydrogen atoms in the phenolic hydroxyl groups in the polymer (A1a-1a) with the t-butoxycarbonylmethyl groups, i.e., a proportion of the t-butoxycarbonylmethyl groups in the total of hydrogen atoms and the t-butoxycarbonylmethyl groups in R^{X}s in the following formula (A1a-1)) was 85%.

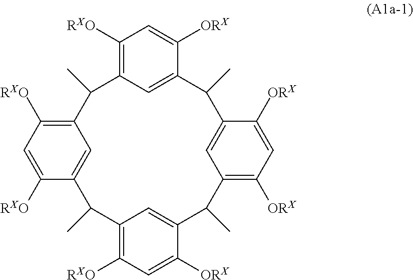

In the above formula (A1a-1), R^{X}s are each independently a hydrogen atom or a t-butoxycarbonylmethyl group.

### Production Example 2

A polymer (A 1 a-2a) was obtained in a similar manner to Production Example 1 except that pyrogallol was used in place of resorcinol, and 3,4-dihydroxybenzaldehyde was used in place of paraldehyde (yield: 45%). In addition, a polymer (A1a-2) was obtained from the polymer (A1a-2a) in a similar manner to Production Example 1 (yield: 30%). The protection rate in the polymer (A1a-2) was 83%.

### Production Example 3

A polymer (A1a-3a) was obtained in a similar manner to Production Example 1 except that pyrogallol was used in place of resorcinol (yield: 53%). In addition, a polymer (A1a-3) was obtained from the polymer (A1a-3a) in a similar manner to Production Example 1 (yield: 42%). The protection rate in the polymer (A1a-3) was 86%.

### Production Example 4

A polymer (A1a-4) was obtained in a similar manner to Production Example 1 except that 4-hydroxybenzaldehyde was used in place of paraldehyde (total yield: 32%). The protection rate in the polymer (A1a-4) was 85%.

### Production Example 5

A polymer (A1a-5) was obtained in a similar manner to Production Example 1 except that 3,4-hydroxybenzaldehyde was used in place of paraldehyde (total yield: 29%). The protection rate in the polymer (A1a-5) was 83%.

### Production Example 6

A monomer solution was prepared by dissolving 20 g of t-butyl acrylate in 40 g of 2-butanone, and further dissolving therein 1.28 g (5 mol % with respect to monomer) of azobisisobutyronitrile (AIBN) as a radical polymerization initiator. Next, a 200-mL three-neck flask containing 20 g of 2-butanone was heated to 80° C. with stirring in a nitrogen atmosphere, and then the prepared monomer solution was added dropwise over 3 hrs. After the completion of the dropwise addition, heating was performed for another 3 hrs at 80° C. to allow the polymerization reaction. After the completion of the polymerization reaction, the reaction solution was cooled to room temperature, then charged into 300 g of methanol, and then the precipitated solid was filtered off. The collected solid was washed twice with 60 mL of methanol. The solid was filtered off, and then the collected solid was dried at 50° C. for 15 hrs under a reduced pressure to obtain a polymer (A1b-1), which was a homopolymer of t-butyl acrylate (amount: 15.7 g; yield: 79%). The polymer (A1b-1) had the Mw of 2,460 and the Mw/Mn of 1.87.

### Production Example 7

A polymer (A 1 b-2), which was a homopolymer of t-butyl crotonate, was obtained in a similar manner to Production Example 6 except that t-butyl crotonate was used in place of t-butyl acrylate (yield: 68%). The polymer (A1b-2) had the Mw of 1,980 and the Mw/Mn of 1.65.

### Production Example 8

A polymer (A1b-3), which was a homopolymer of t-butyl vinyloxyacetate, was obtained in a similar manner to Production Example 6 except that t-butyl vinyloxyacetate was used in place of t-butyl acrylate (yield: 70%). The polymer (A1b-3) had the Mw of 2,110 and the Mw/Mn of 1.71.

### Production Example 9

A polymer (A1b-4), which was a homopolymer of t-butyl 1-propenyloxyacetate, was obtained in a similar manner to Production Example 6 except that t-butyl 1-propenyloxyacetate was used in place of t-butyl acrylate (yield: 58%). The polymer (A1b-4) had the Mw of 2,470 and the Mw/Mn of 1.86.

### Production Example 10

In a mass ratio of 60:30:10, m-cresol, 2,3-xylenol and 3,4-xylenol were mixed. After adding formalin thereto, the mixture was heated at 100° C. for 6 hrs in propylene glycol monomethyl ether as a reaction solvent, with an oxalic acid catalyst. The reaction product was dissolved in ethyl lactate, and then water was blended thereto. An organic layer was collected to obtain a polymer (A1b-5a) (yield: 61%). The polymer (A1b-5a) had the Mw of 8,000. A polymer (A1b-5) was obtained from the polymer (A1b-5a) in a similar manner to Production Example 1. The protection rate in the polymer (A1b-5) was 79%.

### Production Example 11

A polymer (A1b-6) was obtained in a similar manner to Production Example 10 except that 2,7-naphthalenediol was used in place of m-cresol, 2,3-xylenol and 3,4-xylenol (yield: 54%). The polymer (A1b-6) had the Mw of 6,700. The protection rate in the polymer (A1b-6) was 82%.

### Production Example 12

A polymer (A1b-7) was obtained in a similar manner to Production Example 10 except that 2-naphthol and 9,9-bis(4-hydroxyphenyl)fluorene were used in a mass ratio of 40:60, in place of m-cresol, 2,3-xylenol and 3,4-xylenol (yield: 51%). The polymer (A1b-7) had the Mw of 5,200. The protection rate in the polymer (A1b-7) was 84%.

### Production Example 13

A polymer (A1a-6) in which a part of the hydroxy groups in α-cyclodextrin were substituted with the t-butoxycarbonylmethyl groups was obtained in a similar manner to Production Example 1 except that α-cyclodextrin (Wako Pure Chemical Industries, Ltd.) was used in place of the polymer (A1a-1) (yield: 38%). The protection rate in the polymer (A1a-6), i.e., a rate of substitution of hydrogen atoms in the hydroxy groups in α-cyclodextrin with the t-butoxycarbonylmethyl groups, was 59%.

### Production Example 14

A polymer (CA1-1) was obtained in a similar manner to Production Example 1 except that the substitution of hydrogen atoms in the hydroxy groups in the polymer (A1a-1a) was conducted by using 36.5 g of p-chloromethylstyrene in place of tert-butyl bromoacetate (yield: 57%). The ¹H-NMR analysis revealed that the protection rate in the polymer (CA1-1), i.e., a rate of substitution of hydrogen atoms in the phenolic hydroxyl groups in the polymer (A1a-1a) with the p-vinylphenylmethyl groups, was 100%.

### Preparation of Composition for Forming Film for Use in Cleaning

Components used in addition to the component (A) for the preparation of the film-forming composition for cleaning are presented below.

### (B) Solvent

B-1: propylene glycol monomethyl ether acetate
B-2: isopropanol
B-3: γ-butyrolactone
B-4: ethyl lactate

### (C) Thermal Acid Generating Agent

C-1: bis(4-t-butylphenyl)iodonium nonafluoro-n-butanesulfonate (a compound represented by the following formula (C-1))

C-2: triethylammonium nonafluoro-n-butanesulfonate (a compound represented by the following formula (C-2))

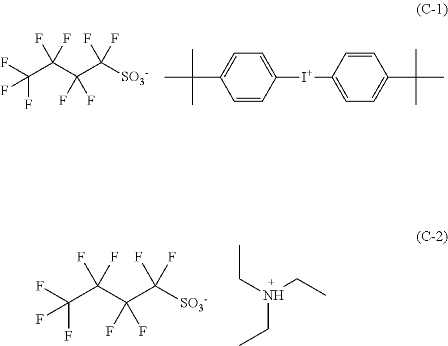

### (D) Surfactant

D-1: Polyflow No. 75 (Kyoeisha Chemical Co., Ltd.)

D-2: Megaface F171 (DIC Corporation)

### Example 1

The polymer (A1a-1) as the polymer (A) in an amount of 100 parts by mass, and 2,000 parts by mass of (B-1) as the solvent (B) were mixed to prepare a homogenous solution. The solution was filtered through a membrane filter having a pore size of 0.1 μm to prepare a film-forming composition for cleaning (J-1).

### Examples 2 to 16 and Comparative Example 1

Film-forming compositions for cleaning (J-2) to (J-16) and (CJ-1) were prepared in a similar manner to Example 1 except that the type and the content of each component used were as shown in Table 1 below. The symbol “−” in Table 1 indicates that the corresponding component was not used.

TABLE 1

| | | | | | | (C) Thermal | | | |
|---|---|---|---|---|---|---|---|---|---|
| | | | | | | acid generating | | | |
| | | (A) Compound | | (B) Solvent | | agent | | (D) Surfactant | |
| | Film-forming | | Content | | Content | | Content | | Content |
| | composition | | (parts by | | (parts by | | (parts by | | (parts by |
| | for cleaning | Type | mass) | Type | mass) | Type | mass) | Type | mass) |
| Example 1 | J-1 | A1a-1 | 100 | B-1 | 2,000 | — | — | — | — |
| Example 2 | J-2 | A1a-2 | 100 | B-2 | 1,250 | — | — | — | — |
| Example 3 | J-3 | A1a-3 | 100 | B-2 | 1,250 | — | — | — | — |
| Example 4 | J-4 | A1a-4 | 100 | B-2 | 2,000 | — | — | D-1 | 0.1 |
| Example 5 | J-5 | A1a-5 | 100 | B-2 | 2,000 | C-1 | 3 | — | — |
| Example 6 | J-6 | A1b-1 | 100 | B-2 | 1,250 | C-1 | 5 | — | — |
| Example 7 | J-7 | A1b-2 | 100 | B-1 | 2,000 | C-2 | 5 | D-2 | 0.1 |
| Example 8 | J-8 | A1b-3 | 100 | B-1 | 1,250 | — | — | — | — |
| Example 9 | J-9 | A1b-4 | 100 | B-1 | 1,250 | — | — | — | — |
| Example 10 | J-10 | A1b-5 | 100 | B-1/B-4 | 1,500/500 | — | — | — | — |
| Example 11 | J-11 | A1b-6 | 100 | B-1 | 2,000 | — | — | — | — |
| Example 12 | J-12 | A1b-7 | 100 | B-1 | 1,250 | C-2 | 3 | — | — |
| Example 13 | J-13 | A1a-6 | 100 | B-1 | 1,250 | — | — | D-2 | 0.1 |
| Example 14 | J-14 | A1a-1a | 100 | B-1/B-3 | 1,500/500 | — | — | — | — |
| Example 15 | J-15 | A1a-2a | 100 | B-2 | 2,000 | — | — | D-1 | 0.1 |
| Example 16 | J-16 | A1a-3a | 100 | B-1 | 2,000 | — | — | — | — |
| Comparative | CJ-1 | CA1-1 | 100 | B-1 | 1,250 | — | — | — | — |
| Example 1 | | | | | | | | | |

### Evaluation of Particle Removability and Film Removability

On a silicon wafer on which silica particles having a diameter of 40 nm had been previously attached, a resin film (film (I)) of each composition was provided by a spin-coating method. The wafer with the resin film thus formed was immersed in the removing liquid, and the resin film was removed. In the case of involving the heat treatment, the heat treatment was carried out at each heating temperature for each heating time period shown in Table 2 below, before immersing in the removing liquid, the wafer on which the resin film had been formed. The film removability was decided to be: “A” when removal of the entire resin film was completed within 20 sec from the starting time point of the immersion in the removing liquid; “B” when the removal was completed later than 20 sec and within 1 min; and “C” when the removal was not completed within 1 min. Furthermore, the number of silica particles left on the wafer after the removing step was analyzed using a defect inspection system in the dark field (“KLA2800”, KLA-TENCOR Corporation). The particle removability was decided to be: “S” when the removal rate of the silica particles was no less than 90%; “A” when the removal rate was no less than 60% and less than 90%; “B” when the removal rate was no less than 30% and less than 60%; and “C” when the removal rate was less than 30%.

### Evaluation Examples 1 to 20 and Comparative Evaluation Examples 1 to 3

Using a silicon wafer as a wafer, any of the compositions (J-1) to (J-16) and the comparative composition (CJ-1) as the film-forming composition for cleaning, and a removing liquid A (a liquid obtained by mixing 28% by mass aqueous ammonia solution/30% by mass aqueous tetramethylammonium hydroxide solution/water in a mass ratio of 1/8/60) or a removing liquid B (2.38% by mass aqueous tetramethylammonium hydroxide solution) as a removing liquid, respectively, as shown in Table 2, the particle removability and the film removability were evaluated according to the evaluation method described above. The results are shown in Table 2.

TABLE 2

| | Film-forming | | | | |
|---|---|---|---|---|---|
| | composition | Heating | Removing | Particle | Film |
| | for cleaning | conditions | liquid | removability | removability |
| Evaluation | J-1 | 200° C., 60 sec | Removing | A | A |
| Example 1 | | | liquid A | | |
| Evaluation | J-2 | 200° C., 60 sec | Removing | S | A |
| Example 2 | | | liquid A | | |
| Evaluation | J-3 | 200° C., 60 sec | Removing | S | A |
| Example 3 | | | liquid A | | |
| Evaluation | J-3 | No heating | Removing | A | B |
| Example 4 | | | liquid A | | |
| Evaluation | J-4 | 200° C., 60 sec | Removing | A | A |
| Example 5 | | | liquid B | | |
| Evaluation | J-5 | 200° C., 60 sec | Removing | A | A |
| Example 6 | | | liquid A | | |
| Evaluation | J-6 | 200° C., 60 sec | Removing | S | A |
| Example 7 | | | liquid A | | |
| Evaluation | J-6 | No heating | Removing | A | B |
| Example 8 | | | liquid A | | |
| Evaluation | J-7 | 170° C., 60 sec | Removing | S | A |
| Example 9 | | | liquid A | | |
| Evaluation | J-7 | No heating | Removing | A | B |
| Example 10 | | | liquid A | | |
| Evaluation | J-8 | 200° C., 60 sec | Removing | A | A |
| Example 11 | | | liquid A | | |
| Evaluation | J-9 | 200° C., 60 sec | Removing | A | A |
| Example 12 | | | liquid A | | |
| Evaluation | J-10 | 200° C., 60 sec | Removing | A | A |
| Example 13 | | | liquid A | | |
| Evaluation | J-11 | 200° C., 60 sec | Removing | A | A |
| Example 14 | | | liquid B | | |
| Evaluation | J-11 | No heating | Removing | B | B |
| Example 15 | | | liquid A | | |
| Evaluation | J-12 | 170° C., 60 sec | Removing | A | A |
| Example 16 | | | liquid A | | |
| Evaluation | J-13 | 200° C., 60 sec | Removing | A | A |
| Example 17 | | | liquid A | | |
| Evaluation | J-14 | 200° C., 60 sec | Removing | B | B |
| Example 18 | | | liquid B | | |
| Evaluation | J-15 | 200° C., 60 sec | Removing | B | B |
| Example 19 | | | liquid A | | |
| Evaluation | J-16 | 200° C., 60 sec | Removing | B | B |
| Example 20 | | | liquid A | | |
| Comparative | CJ-1 | No heating | Removing | C | C |
| Evaluation | | | liquid A | | |
| Example 1 | | | | | |
| Comparative | CJ-1 | No heating | Removing | C | C |
| Evaluation | | | liquid B | | |
| Example 2 | | | | | |
| Comparative | CJ-1 | 200° C., 60 sec | Removing | C | C |
| Evaluation | | | liquid A | | |
| Example 3 | | | | | |

A comparison of each Evaluation Example with each Comparative Evaluation Example reveals that the film-forming composition for cleaning according to the embodiment of the present invention was superior in both the particle removability and the film removability in the cleaning method for a semiconductor substrate which includes providing a film on the substrate surface, and removing the same.

According to the composition for forming a film for use in cleaning a semiconductor substrate of the embodiment of the present invention, in processes of removing unwanted substances on the substrate surface through forming a film on the substrate surface, the composition is capable of efficiently removing particles on the substrate surface, and enables the formed film to be easily removed from the substrate surface. Furthermore, the cleaning method for a semiconductor substrate of the embodiment of the present invention is capable of efficiently removing particles on the substrate surface, while easily removing the formed film from the substrate surface. Therefore, the composition for forming a film for use in cleaning a semiconductor substrate and the cleaning method for a semiconductor substrate of the embodiments of the present invention can be suitably used in production of semiconductor elements in which further progress of miniaturization, and an increase of the aspect ratio are expected in the future.

Obviously, numerous modifications and variations of the present invention are possible in light of the above teachings. It is therefore to be understood that within the scope of the appended claims, the invention may be practiced otherwise than as specifically described herein.

1. A composition for forming a film for use in cleaning a semiconductor substrate, comprising:
a solvent; and
a compound having a molecular weight of no less than 300 and comprising
a polar group,
a group represented by formula (i):
—O—R¹ (i)
wherein in the formula (i), R¹ represents a group that is dissociated by heat or an action of an acid, or a combination thereof.

2. The composition according to claim 1, wherein the compound comprises the group represented by the formula (i).

3. The composition according to claim 1, wherein the polar group is a hydroxy group, a carboxy group, an amide group, an amino group, a sulfonyl group, a sulfo group or a combination thereof.

4. The composition according to claim 1, wherein the compound is a polymer having a weight average molecular weight of no less than 300 and no greater than 50,000.

5. The composition according to claim 4, wherein the polymer is a ring polymer having a weight average molecular weight of no less than 300 and no greater than 3,000.

6. The composition according to claim 1, wherein the solvent is water, a polar organic solvent or a combination thereof.

7. The composition according to claim 6, wherein the polar organic solvent is an alcohol, a polyhydric alcohol alkyl ether or a combination thereof.

8. The composition according to claim 6, wherein a content of water in the solvent is no greater than 20% by mass.

9. The composition according to claim 1, further comprising a thermal acid generating agent.

10. The composition according to claim 1, wherein a content of the compound is no less than 0.1% by mass and no greater than 50% by mass.

11. A cleaning method for a semiconductor substrate, comprising:
applying the composition according to claim 1 on a surface of the semiconductor substrate to form a film for cleaning the semiconductor substrate; and
removing the film from the substrate.
